(19) United States
(12) Patent Application Publication
(10) Pub. No.: US 2025/0120010 A1
(43) Pub. Date: Apr. 10, 2025

(54) WIRING BOARD

(71) Applicant: SHINKO ELECTRIC INDUSTRIES CO., LTD., Nagano-shi (JP)

(72) Inventors: Tatsuki Sumi, Aichi (JP); Kei Murayama, Nagano (JP); Yoshihiro Machida, Nagano (JP); Hiroshi Taneda, Nagano (JP); Makoto Tsukahara, Nagano (JP)

(21) Appl. No.: 18/902,065

(22) Filed: Sep. 30, 2024

(30) Foreign Application Priority Data
Oct. 6, 2023 (JP) 2023-174699

(51) Int. Cl. H05K 1/02; H05K 1/11; H05K 3/06; H05K 3/40

(52) U.S. Cl. CPC H05K 1/0274; H05K 1/113; H05K 3/061; H05K 3/4038; H05K 2201/09409; H05K 2201/096; H05K 2201/09609; H05K 2201/10121; H05K 2201/10242; H05K 2203/0723; H05K 2203/107

(57) ABSTRACT

A wiring board includes a layered structure and a waveguide. The layered structure include multiple insulating layers that are laminated. The waveguide is formed inside the layered structure. The waveguide includes a pair of conductive layers, and multiple conductive pillars. The pair of the conductive layers face each other in a lamination direction of the insulating layers. The multiple conductive pillars are arranged in two rows along a propagation direction of electromagnetic waves between the pair of the conductive layers, and connects the pair of the conductive layers. The respective conductive pillars include multiple connection pads and a via. The connection pads are laminated between the pair of the conductive layers. The via connects the connection pads of adjacent layers, and has a cross-section perpendicular to the lamination direction in a rectangular shape.

### CROSS-REFERENCE TO RELATED APPLICATION

This application is based upon and claims the benefit of priority of the prior Japanese Patent Application No. 2023-174699, filed on Oct. 6, 2023, the entire contents of which are incorporated herein by reference.

### FIELD

The embodiment discussed herein is related to a wiring board.

### BACKGROUND

Conventionally, a wiring board has been known in which a waveguide for transmitting electromagnetic waves is formed in a multilayer structure with multiple insulating layers. The waveguide formed within the multilayer structure is generally constituted of a pair of conductor layers facing each other in a lamination direction of the multiple insulating layers, and multiple cylindrical conductor pillars arranged along a transmission direction of the electromagnetic waves between the pair of conductor layers (for example, Japanese Patent No. 5209610). However, in the wiring board with the waveguide described above, there is a problem that an electromagnetic wave leaks to the outside of the waveguide through a gap between the cylindrical conductor pillars. That is, because a cross-section of each cylindrical conductor pillar perpendicular to a direction of thickness of the wiring board is circular, the gaps between adjacent conductor pillars become larger from the center of each conductive pillar toward the peripheral edge along a direction of width of the waveguide. Therefore, there is a possibility that electromagnetic waves easily leak out of the waveguide through the gaps between adjacent conductor pillars. The leakage of electromagnetic waves from the waveguide can cause crosstalk with various wiring within the wiring board, and is undesirable.

### SUMMARY

According to an aspect of an embodiment, a wiring board includes a layered structure including a plurality of insulating layers that are laminated; and a waveguide that is formed inside the layered structure, wherein the waveguide includes a pair of conductive layers facing each other in a lamination direction of the insulating layers; and a plurality of conductive pillars that are arranged in two rows along a propagation direction of electromagnetic waves between the pair of the conductive layers, and that connect the pair of the conductive layers, and the respective conductive pillars include a plurality of connection pads that are laminated between the pair of conductive layers; and a via that connects the connection pads of adjacent layers, and that has a cross-section perpendicular to the lamination direction in a rectangular shape.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to an embodiment;

FIG. 2 is a cross-section of a waveguide according to the embodiment cut along a plane perpendicular to a lamination direction;

FIG. 3 is a flowchart illustrating a manufacturing method of the wiring board according to the embodiment;

FIG. 4 is a diagram illustrating a specific example of a core board;

FIG. 5 is a diagram illustrating a specific example of a first-conductive-layer formation process;

FIG. 6 is a diagram illustrating a specific example of an insulation-layer formation process;

FIG. 7 is a diagram illustrating a specific example of a metal-foil lamination process;

FIG. 8 is a diagram illustrating a specific example of a metal-foil patterning process;

FIG. 9 is a diagram illustrating a specific example of a shape of an opening portion;

FIG. 10 is a diagram illustrating a specific example of a via-hole formation process;

FIG. 11 is a diagram illustrating a specific example of a laser irradiation range;

FIG. 12 is a diagram illustrating a specific example of a seed-layer formation process;

FIG. 13 is a diagram illustrating a specific example of a resist-layer formation process;

FIG. 14 is a diagram illustrating a specific example of an electrolytic-copper plating process;

FIG. 15 is a diagram illustrating a specific example of a resist-layer removal process;

FIG. 16 is a diagram illustrating a specific example of a flash-etching process;

FIG. 17 is a diagram illustrating a specific example of an insulating-layer formation process;

FIG. 18 is a diagram illustrating a specific example of a second-conductive-layer formation process;

FIG. 19 is a diagram illustrating simulation results of an electric field strength of electromagnetic waves leaking from the waveguide in the wiring board according to the embodiment and a comparative example;

FIG. 20 is a cross-section of a waveguide according to a first modification of the embodiment in a direction perpendicular to a lamination direction;

FIG. 21 is a cross-section of a waveguide according to a second modification of the embodiment in a direction perpendicular to a lamination direction;

FIG. 22 is a diagram illustrating a wiring board according to a third modification of the embodiment; and

FIG. 23 is a cross-section of a waveguide according to a third modification of the embodiment cut on a plane perpendicular to the lamination direction.

### DESCRIPTION OF EMBODIMENT

Hereinafter, an embodiment of a wiring board disclosed in the present application will be explained in detail based on the drawings. This embodiment is not intended to limit the disclosed technique.

### Embodiment

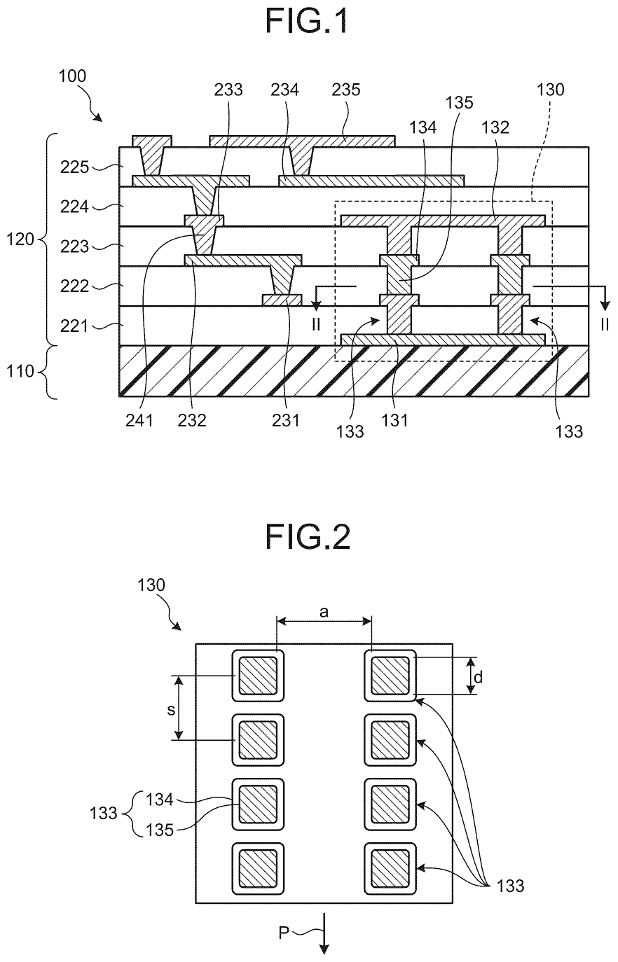

FIG. 1 is a diagram illustrating a configuration of a wiring board 100 according to the embodiment. FIG. 1 schematically illustrates a cross-section of the wiring board 100.

The wiring board 100 has a layered structure, and includes a core substrate 110 and a multilayer wiring structure 120. In the following explanation, a direction from the core substrate 110 toward the multilayer wiring structure 120 is referred to as “upward direction”, and a direction from the multilayer wiring structure 120 toward the core substrate 110 is referred to as “downward direction”. However, the wiring board 100 may be manufactured and used in any orientation, such as upside down.

The core substrate 110 is a substrate made of a plate-shaped insulating material.

The multilayer wiring structure 120 has a layered structure in which an insulating layer and a conductive layer are laminated. That is, the multilayer wiring structure 120 includes insulating layers 221 to 225, conductive layers 231 to 235, a first conductive layer 131, and a second conductive layer 132 (one example of a pair of conductive layers).

The insulating layers 221 to 225 are formed using a heat-resistant, non-photosensitive, and thermosetting insulating resin, such as epoxy resin, polyimide resin, and cyanate resin. The thickness of the insulating layers 221 to 225 can be set to, for example, approximately 40 μm to 80 μm.

The conductive layers 231 to 235 are formed an upper surface of the insulating layers 221 to 225, respectively. The conductive layers 231 to 235 is formed using, for example, copper or copper alloy. The thickness of the conductive layers 231 to 235 can be set to, for example, approximately 18 μm to 20 μm. The conductive layers 231 to 235 adjacent to each other through the insulating layers 221 to 225 are electrically connected as necessary through a via 241 that pierces through the insulating layers 221 to 225.

The first conductive layer 131 is formed on an upper surface of the core substrate 110. The first conductive layer 131 is formed using, for example, copper or copper alloy. The thickness of the first conductive layer 131 can be set to, for example, approximately 18 μm to 20 μm.

The second conductive layer 132 is formed on an upper surface of the insulating layer 223 so as to face the first conductive layer 131. The second conductive layer 132 is formed using, for example, copper or copper alloy, together with the conductive layer 233. The thickness of the second conductive layer 132 can be set to, for example, approximately 18 μm to 20 μm, similarly to the conductive layer 233. The first conductive layer 131 and the second conductive layer 132 are electrically connected through a multiple layered connection pad 134 and a via 135. That is, a portion between the first conductive layer 131 and the connection pad 134, the adjacent connecting pad 134, and a portion between the connection pad 134 and the second conductive layer 132 are connected by the via 135.

In the configuration in FIG. 1, two layers of the connection pads 134 are laminated between the first conductive layer 131 and the second conductive layer 132. The two layers of the connection pads 134 are formed on the same layer as the conductive layers 231 and 232, respectively. The thickness of the connection pad 134 can be set to, for example, approximately 18 μm to 20 μm, similarly to the conductive layers 231, 232. In the following, they may be referred to as the connection pads 134 of first to second layers, respectively, sequentially from the connection pad 134 positioned close to the first conductive layer 131.

The insulating layer 221 is a layer that covers the first conductive layer 131, and that has a conductive layer 231 and the connection pad 134 of the first layer formed on its upper surface. The conductive layer 231 and the connection pad 134 of the first layer are formed on the upper surface of the insulating layer 221 by, for example, the modified semi-additive process (MSAP). The connection pad 134 of the first layer is electrically connected to the first conductive layer 131 through the via 135 that pierces through the insulating layer 221.

The insulating layer 222 is layer that covers the conductive layer 231 and the connection pad 134 of the first layer, and that has a conductive layer 232 and the connection pad 134 of the second layer formed on its upper surface. The conductive layer 232 and the connection pad 134 of the second layer are formed on the upper surface of the insulating layer 222 by, for example, the MSAP. The conductive layer 232 is electrically connected to the conductive layer 231 through the via 241 that pierces through the insulating layer 222. The connection pad 134 of the second layer is electrically connected to the connection pad 134 of the first layer through the via 135 that pierces through the insulating layer 222.

The insulating layer 223 is a layer that covers the conductive layer 232 and the connection pad 134 of the second layer, and that has the conductive layer 233 and the second conductive layer 132 formed on its upper surface. The conductive layer 233 and the second conductive layer 132 are formed on the upper surface of the insulating layer 223 by, for example, the MSAP. The conductive layer 233 is electrically connected to the conductive layer 232 through the via 241 that pierces through the insulating layer 223. The second conductive layer 132 is electrically connected to the connection pad 134 of the second layer through the via 135 that pierces through the insulating layer 223.

The insulating layer 224 is a layer that covers the conductive layer 233 and the second conductive layer 132, and that has the conductive layer 234 formed on its upper surface. The conductive layer 234 is formed on the upper surface of the insulating layer 224 by, for example, the MSAP. The conductive layer 234 is electrically connected to the conductive layer 233 through the via 241 that pierces through the insulating layer 224.

The insulating layer 225 is a layer that covers the conductive layer 234, and that has the conductive layer 235 formed on its upper surface. The conductive layer 235 is formed on the upper surface of the insulating layer 225 by, for example, the MSAP. The conductive layer 235 is electrically connected to the conductive layer 234 through the via 241 that pierces through the insulating layer 225. On the conductive layer 235, a mounting pad to mount an electronic part, such as a semiconductor chip, is formed.

In the multilayer wiring structure 120, a waveguide 130 is formed. The waveguide 130 is formed surrounding a portion of the insulating layers 221 to 223 of the multilayer wiring structure 120. Out of the insulating layers 221 to 223, the portion surrounded by the waveguide 130 functions as a waveguide that propagates electromagnetic waves. The waveguide 130 includes the first conductive layer 131, the second conductive layer 132, and multiple conductive pillars 133.

The first conductive layer 131 and the second conductive layer 132 are a pair of conductive layers that face each other in the lamination direction of the insulating layers 221 to 225 of the multilayer wiring structure 120 (that is, a direction of thickness of the multilayer wiring structure 120, hereinafter, simply referred to as “lamination direction”).

The multiple conductive pillars 133 are arranged in two rows along a propagation direction P (refer to FIG. 2) of electromagnetic waves between the first conductive layer 131 and the second conductive layer 132, and connect the first conductive layer 131 and the second conductive layer 132.

The respective conductive pillars 133 are formed by laminating the multiple (two layers in the example of FIG. 1) connection pads 134 between the first conductive layer 131 and the second conductive layer 132, and by connecting the connection pad 134 of the adjacent layer and the via 135.

FIG. 2 is a cross-section of the waveguide 130 according to the embodiment cut on a plane perpendicular to the lamination direction. FIG. 2 corresponds to a cross-section of the waveguide 130 taken along a line II-II in FIG. 1.

As described above, in the waveguide 130, the multiple conductive pillars 133 are arranged in two rows along the propagation direction P of electromagnetic waves between the first conductive layer 131 and the second conductive layer 132. The waveguide 130 constituted of these first conductive layer 131, the second conductive layer 132, and the multiple conductive pillars 133 can be regarded as a rectangular waveguide.

In the waveguide 130, a gap is formed between the conductive pillars 133 adjacent to each other along the propagation direction P of electromagnetic waves. A condition for suppressing leakage of electromagnetic waves from the gap between the adjacent conductive pillars 133 is expressed by Equations 1 and 2, where a pitch of the via 135 of the respective conductive pillars 133 is s, and a width of the via 135 is d.

$$s \leq 2 d \qquad ( 1 )$$

$$d \leq {λ}_{g} / 5 \qquad ( 2 )$$

In Equation 2, λ_{g} represents a guide wavelength of electromagnetic waves propagating in a TE₁₀ mode within the waveguide 130, which is a rectangular waveguide. λ_{g} is expressed by Equation 3 below, where a wavelength of an electromagnetic wave in free space is λ, and an interval of the via 135 in a width direction of the waveguide 130 is a.

$$λ g = λ / √ \{ 1 - {( λ / 2 a )}^{2} \} \qquad ( 3 )$$

Suppose that an electromagnetic wave having a frequency of 150 (GHz) is propagated in the TE₁₀ mode through the waveguide 130, which is a rectangular waveguide. In this case, for example, a cutoff wavelength λ_{c} can be set to 2a=1.5λ. Therefore, when the inside of the waveguide 130 is filled with insulating resin with a relative permittivity of 3.3, the interval a of the via 135 in a direction of width of the waveguide 130, the width d of the via 135 of the respective conductive pillars 133, and the pitch s of the via 135 can be set, for example, based on following Equations 4 and 5.

$$a = 830 ( µm ) \qquad ( 4 )$$

$$s / 2 \leq d \leq 300 ( µm ) \qquad ( 5 )$$

In the embodiment, the via 135 of the respective conductive pillars 133 has a cross section perpendicular to the lamination direction in a rectangular shape (in FIG. 2, in a square shape as an example). That is, the via 135 has a prismatic shape as a whole. Therefore, it is possible to reduce the gap between the adjacent conductive pillars 133 compared to a case in which a cross-section perpendicular to the lamination direction of the via of the respective conductive pillars is in a circular shape (that is, when a via has a cylindrical shape). This enables to reduce a possibility of electromagnetic waves passing through the gap between the adjacent conductive pillars 133 to the outside of the waveguide 130. As a result, leakage of electromagnetic waves from the waveguide 130 can be suppressed.

Moreover, the via 135 may have a cross-section perpendicular to the lamination direction in a rounded rectangular shape. That is, four corners of the rectangular via 135 may be rounded. This enables to reduce concentration of a stress due to a difference in thermal expansion coefficients of the insulating resin and the via 135 on corners of via holes formed in the insulating layers 221 and 222 (refer to FIG. 1) for the via 135 in a rectangular shape. As a result, it is possible to reduce a possibility of delamination and damage of the insulating layers 221, 222, and the via 135.

In the embodiment, the respective connection pads 134 of the respective conductive pillars 133 are in a rectangular shape in plan view (in FIG. 2, square shape as an example). Therefore, the gap between the adjacent conductive pillars 133 can be further reduced partially, compared to a case in which the respective connection pad of the respective conductive pillars are in a circular shape in plan view. This enables to further reduce a possibility of electromagnetic waves passing through a gap between the adjacent conductive pillars 133 to the outside of the waveguide 130. As a result, it is possible to further reduce leakage of electromagnetic waves from the waveguide 130.

Moreover, the respective connection pads 134 may have a rounded rectangular shape in plan view. That is, four corners of the respective connection pads 134 in a rectangular shape may be rounded. This enables to reduce concentration of a stress due to a difference in thermal expansion coefficients of the insulating resin and the respective connection pads 134 caused on the insulating layers 222, 223 (refer to FIG. 1) that cover the respective connection pads 134 in a rectangular shape. As a result, it is possible to reduce a possibility of delamination and damage of the insulating layers 222, 223, and the respective connection pads 134.

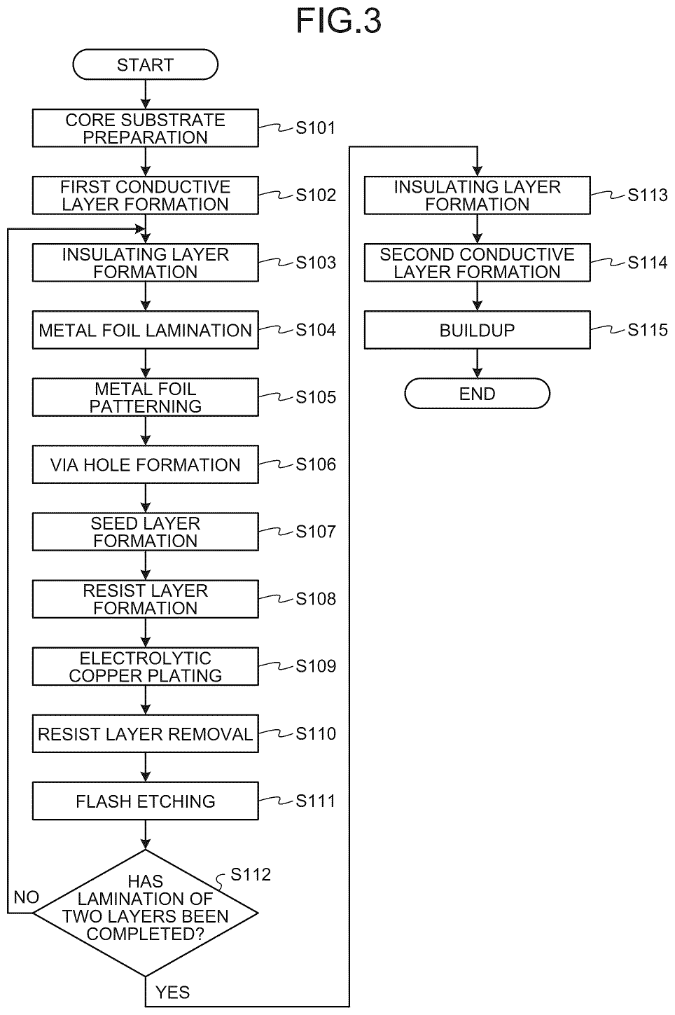

Next, a manufacturing method of the wiring board 100 configured as described above will be explained with specific examples referring to FIG. 3. FIG. 3 is a flowchart illustrating a manufacturing method of the wiring board 100 according to the embodiment. In the following, specific examples of the respective processes will be explained focusing on the waveguide 130 in the wiring board 100.

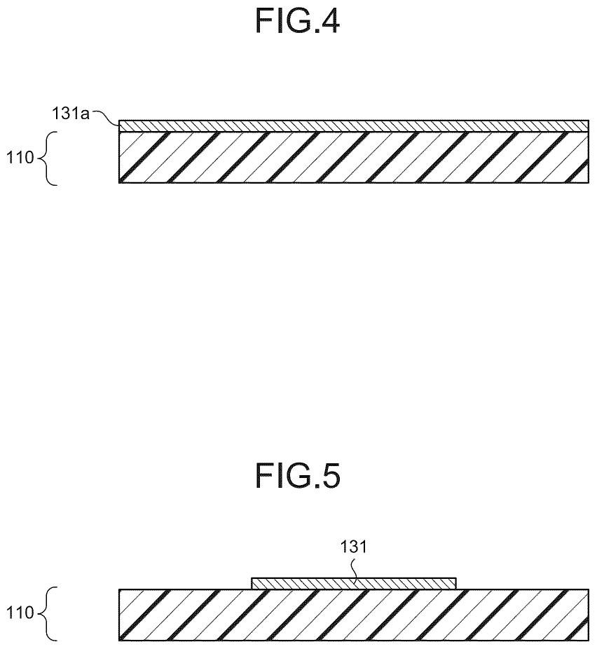

First, the core substrate 110 to be a substrate for manufacturing the wiring board 100 is prepared (step S101). Specifically, for example, as illustrated in FIG. 4, the core substrate 110 with the first conductive layer 131 and a conductive foil 131a provided in advance on its upper surface is prepared. FIG. 4 is a diagram illustrating a specific example of the core substrate 110. As the conductive foil 131a, for example, copper foil, copper alloy foil, or the like can be used. The thickness of the conductive foil 131a is, for example, 12 μm to 18 μm.

Thereafter, the first conductive layer 131 is formed on the upper surface of the core substrate 110 (step S102). The first conductive layer 131 is formed from the conductive foil 131a by, for example, the subtractive method. In this case, a resist layer that covers a portion other than a portion subject to etching is formed on the conductive foil 131a. Subsequently, a portion not covered by the resist layer is removed from the conductive foil 131a by etching. Thereafter, by removing the resist layer from a remaining portion of the conductive foil 131a, the first conductive layer 131 can be obtained, for example, as illustrated in FIG. 5. FIG. 5 is a diagram illustrating a specific example of a first conductive-layer formation process.

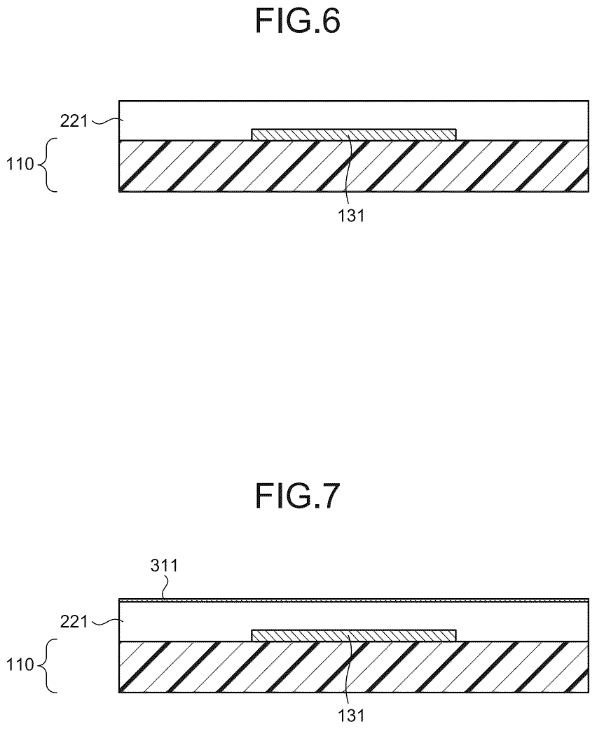

After the first conductive layer 131 is formed, for example, as illustrated in FIG. 6, the insulating layer 221 is formed to cover the first conductive layer 131 on the core substrate 110 (step S103). FIG. 6 is a diagram illustrating a specific example of an insulating-layer formation process. That is, on the first conductive layer 131, the insulating layer 221 that is formed using heat-resistant, non-photosensitive, and thermosetting insulating resins such as epoxy resin, polyimide resin, and cyanate resin is laminated. The thickness of the insulating layer 221 is, for example, approximately 40 μm to 80 μm.

After the insulating layer 221 is formed, the connection pad 134 of the first layer is formed on the upper surface of the insulating layer 221 by the MSAP. Specifically, for example, as illustrated in FIG. 7, a metal foil 311 made of a metal, such as copper or copper alloy is laminated on the upper surface of the insulating layer 221 (step S104). FIG. 7 is a diagram illustrating a specific example of the metal-foil lamination process. The thickness of the metal foil 311 is, for example, approximately 1.5 μm to 5 μm.

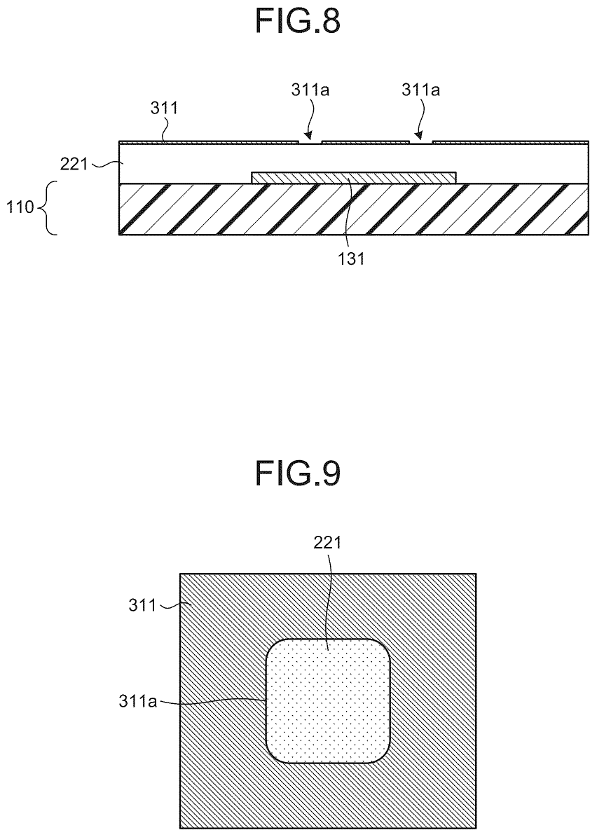

Thereafter, by patterning of the metal foil 311, an opening portion is formed at a position at which the via 135 is to be formed (step S105). That is, for example, as illustrated in FIG. 8, an opening portion 311a piercing through the metal foil 311 to expose the insulating layer 221 to a bottom surface is formed. FIG. 8 is a diagram illustrating a specific example of a metal-foil patterning process. In the metal foil 311, the multiple opening portions 311a arranged in two row along the propagation direction P (refer to FIG. 2) of electromagnetic waves are formed.

The patterning of the metal foil 311 is achieved by for example, the subtractive method. In this case, the resist layer in which an opening is formed at a position at which the via 135 is formed is formed on the metal foil 311. Subsequently, the metal foil 311 that is exposed from the opening of the resist layer is removed by etching. Thereafter, by removing the resist layer, the metal foil 311 having the opening portion 311a at the position at which the via 135 is formed is obtained.

FIG. 9 is a diagram illustrating a specific example of a shape of the opening portion 311a. As illustrated in FIG. 9, the opening portion 311a of the metal foil 311 has a rectangular shape in plan view (a square shape as an example). To the bottom surface of the opening portion 311a, the insulating layer 221 is exposed. The opening portion 311a may have a rounded rectangular shape in plan view. That is, four corners of the opening portion 311a in a rectangular shape may be rounded.

After the opening portion 311a is formed by pattering of the metal foil 311, a via hole is formed in the insulating layer 311a by laser processing using the metal foil 311 having the opening portion 311a as a mask (step S106). Specifically, a laser is irradiated to the insulating layer 221 that is exposed from the opening portion 311a of the metal foil 311, a via hole 221a that pierces through the insulating layer 221 and exposes the first conductive layer 131 to the bottom surface is formed at a position corresponding to the via 135, for example, as illustrated in FIG. 10. FIG. 10 is a diagram illustrating a specific example of a via-hole formation process. Because the opening portion 311a of the metal foil 311 has a rectangular shape in plan view, the via hole 221a has a rectangular shape in plan view. That is, in the insulating layer 221, the via hole 221a having a prismatic shape is formed. Moreover, in the insulating layer 221, the multiple via holes 221a arranged in two rows along the propagation direction P (refer to FIG. 2) of electromagnetic waves are formed.

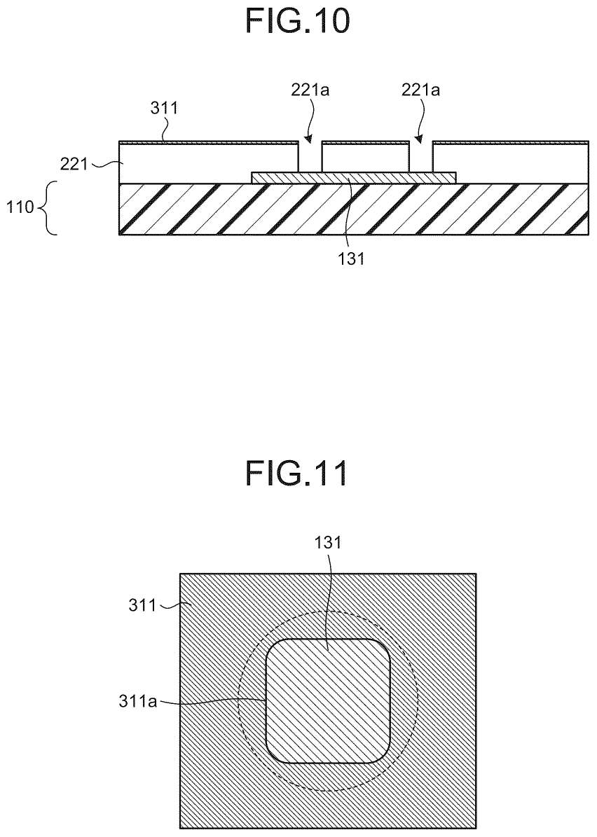

When the via hole 221a is formed by the laser processing, a spot diameter of the laser irradiated to the opening portion 311a of the metal foil 311 is preferable to be larger than a diameter of the opening portion 311a. That is, as indicated by a broken line in FIG. 11, an irradiation range of the laser is preferable to include the entire opening portion 311a. FIG. 11 is a diagram illustrating a specific example of the irradiation range of the laser.

The residual insulating resin (smear) generated by the laser processing is removed by a desmearing treatment using, for example, a potassium permanganate solution.

After formation of the via hole 221a, a seed layer is formed by electroless plating (step S107). Specifically, for example, as illustrated in FIG. 12, a seed layer 311b is formed by subjecting a surface of the metal foil 311 and an inner wall surface of the via hole 221a to, for example, electroless copper plating. FIG. 12 is a diagram illustrating a specific example of a seed-layer formation process. The thickness of the seed layer 311b is, for example, approximately 0.5 μm to 1 μm. The seed layer 311b continuously covers the inner wall surface of the via hole 221a and the upper surface of the first conductive layer 131 exposed to the bottom surface of the via hole 221a.

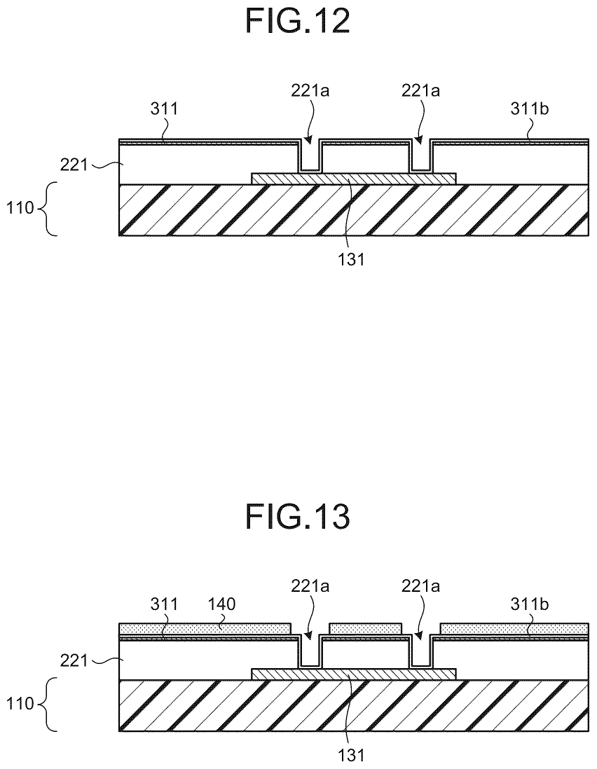

After the seed layer 311b is formed, the resist layer to be used as a mask for electrolytic copper plating is formed (step S108). That is, a dry film resist (DRF) is laminated on the seed layer 311b, and by performing exposure and development according to a position of the via hole 221a, for example, as illustrated in FIG. 13, a resist layer 140 that has an opening portion at the position of the via hole 221a is formed. FIG. 13 is a diagram illustrating a specific example of the resist-layer formation process. Because the connection pad 134 and the via 135 are formed at a position of the via hole 221a, the opening portion of the resist layer 140 is arranged at the position of the via hole 221a. The opening portion of the resist layer 140 has a rectangular shape (a square shape as an example) with a width larger than the via hole 221a in a rectangular shape in plan view. Although illustration is omitted, in the resist layer 140, another opening portion to form the conductive layer 231 is formed. The other portion of the resist layer 140 is, for example, in a circular shape in plan view.

Subsequently, by electrolytic copper plating using the seed layer 311b as a power supply layer, the connection pad 134 of the first layer and the via 135 are formed on the seed layer 311b that is exposed from the opening portion of the resist layer 140 (step S109). Specifically, for example, as illustrated in FIG. 14, the via 135 is formed as the electrolytic copper is filled in the via hole 221a to form the via 135, and copper is precipitated into the opening portion of the resist layer 140 to form the connection pad 134 of the first layer. FIG. 14 is a diagram illustrating a specific example of an electrolytic-copper plating process. Because the via hole 221a has a prismatic shape, the via 135 has a prismatic shape. Moreover, because the opening portion of the resist layer 140 has a rectangular shape in plan view. the connection pad 134 of the first layer has a rectangular shape in plan view. In the electrolytic-copper plating process at this step S109, electrolytic copper is filled in the other opening portion (not illustrated) of the resist layer 140, to form the conductive layer 231.

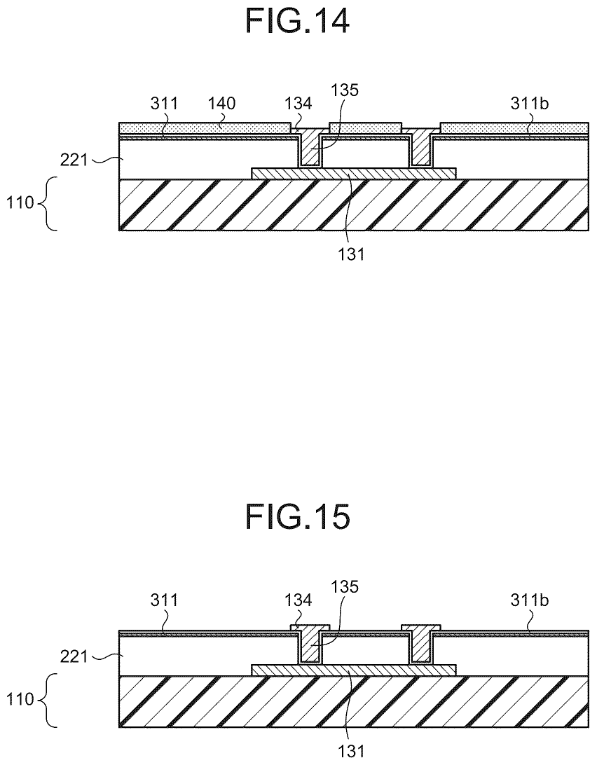

After the electrolytic copper plating, for example, as illustrated in FIG. 15, the resist layer 140 is removed (step S110). FIG. 15 is a diagram illustrating a specific example of a resist-layer removal process. For removal of the resist layer 140, for example, caustic soda or amine-based alkaline stripping solution is used.

After the resist layer 140 is removed, unnecessary portions of the seed layer 311b and the metal foil 311 are removed by flash etching (step S111). That is, for example, as illustrated in FIG. 16, the seed layer 311b and the metal foil 311 other than a portion in contact with the connection pad 134 of the first layer and the via 135 are removed. FIG. 16 is a diagram illustrating a specific example of a flash etching process. Although the seed layer 311b and the metal foil 311 in contact with the connection pad 134 of the first layer and the via 135 remain even after the flash etching, illustration thereof is omitted in FIG. 16.

In the multilayer wiring structure 120, the waveguide 130 is formed surrounding a portion of the insulating layers 221 to 223, and whether lamination of the insulating layers of the bottom most layer to the second layer (namely, the insulating layer 221, 222) out of the insulating layers 221 to 223 has been completed is determined (step S112). When lamination of the insulating layers up to the second layer has not completed (step S112: NO), the process similar to the process at step S103 to S111 described above is repeated, and the insulating layers 221, 222, and the connection pad 134 of the second layer are laminated in a state in which the connection pad 134 of the adjacent layer is connected by the via 135. Moreover, the conductive layer 232 is formed on the upper surface of the insulating layer 222 together with the connection pad 134 of the second layer, and the conductive layer 232 and the conductive layer 231 are electrically connected through the via 241 piercing through the insulating layer 222.

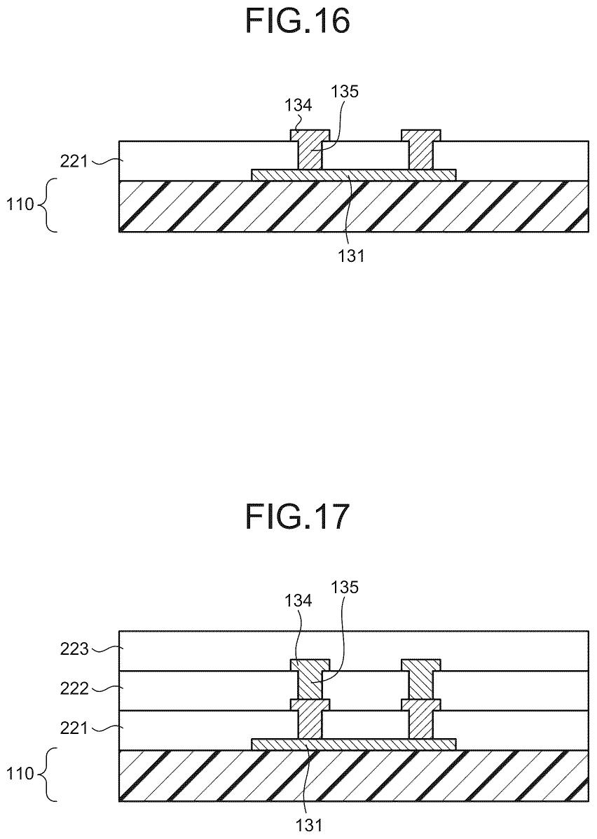

On the other hand, when lamination up to the second layer has been completed (step S112: YES), for example, as illustrated in FIG. 17, the insulating layer 223 that covers the connection pad 134 of the second layer, and that is the topmost layer is formed (step S113). FIG. 17 is a diagram illustrating a specific example of an insulating-layer formation process. That is, the insulating layer 223 that is formed using heat-resistant, non-photosensitive, and thermosetting insulating resins such as epoxy resin, polyimide resin, and cyanate resin is laminated on the connection pad 134 of the second layer. The thickness of the insulating layer 223 is, for example, approximately 40 μm to 80 μm.

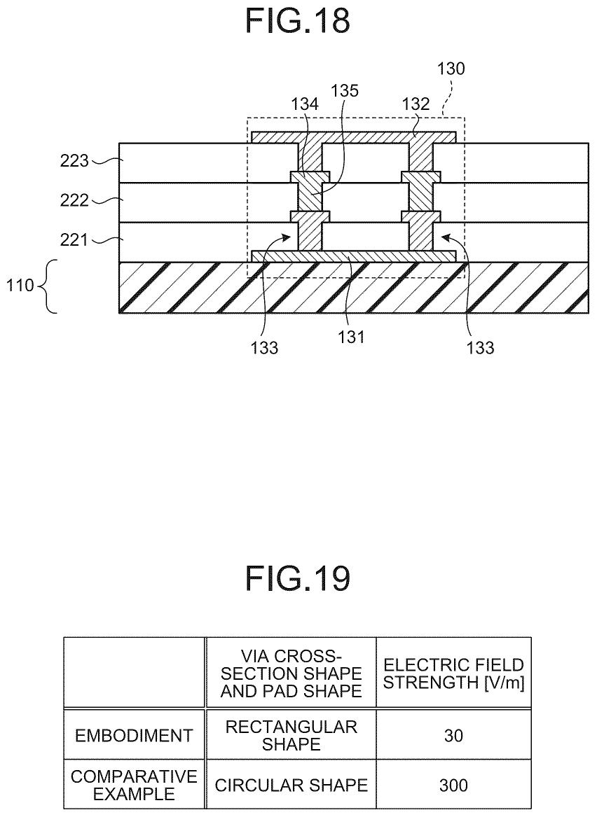

When the insulating layer 223 is formed, the second conductive layer 132 facing the first conductive layer 131 is formed on the upper surface of the insulating layer 223 by the MSAP, for example, as illustrated in FIG. 18 (step S114). FIG. 18 is a diagram illustrating a specific example of a second-conductive-layer formation process. At formation of the second conductive layer 132, the via 135 that pierces through the insulating layer 223 is formed in the insulating layer 223, and with the via 135, the second conductive layer 132 and the connection pad 134 of the second layer are electrically connected. Thus, the multiple conductive pillars 133 that are arranged in two rows along the propagation direction P (refer to FIG. 2) of the electromagnetic waves and that connect the first conductive layer 131 and the second conductive layer 132 are formed between the first conductive layer 131 and the second conductive layer 132. Moreover, the conductive layer 233 is formed on the upper surface of the insulating layer 233 together with the second conductive layer 132, and the conductive layer 233 and the conductive layer 232 are electrically connected through the via 241 that pierces through the insulating layer 223.

As the multiple conductive pillars 133 are formed, an intermediate structure is obtained in which the waveguide 130 having the first conductive layer 131, the second conductive layer 132, and the multiple conductive pillars 133 is arranged therein.

Thereafter, the insulating layers 224, 225 and the conductive layers 234, 235 are laminated on an upper surface of the intermediate structure by a buildup method, and the multilayer wiring structure 120 is formed (step S115). As the multilayer wiring structure 120 is formed, the wiring board 100 in which the waveguide 130 is arranged therein is completed.

In the following, simulation results of electric field strength of electromagnetic waves leaking from a waveguide will be explained with reference to FIG. 19, using the wiring board according to the embodiment and a wiring board according to a comparative example as examples. FIG. 19 is a diagram illustrating simulation results of electric field strength of electromagnetic waves leaking from the waveguide in the wiring board according to the embodiment and a comparative example.

In the waveguide of the wiring board according to the embodiment, a cross-section perpendicular to the lamination direction of the via of the respective conductive pillars has a rectangular shape, and the respective connection pads of the respective conductive pillars have a rectangular shape in plan view. In the waveguide of this wiring board, an electric field strength of electromagnetic waves measured at a predetermined area positioned outward in a width direction of the waveguide relative to the gap between the adjacent conductive pillars was 30 (V/m).

On the other hand, in the waveguide of the wiring board according to the comparative example, a cross section perpendicular to the lamination direction of the via of the respective conductive pillars has a circular shape, and the respective connection pads of the respective conductive pillars have a circular shape in plan view. In the waveguide of this wiring board, an electric field strength of electromagnetic waves measured at a predetermined area positioned outward in a width direction of the waveguide relative to the gap between the adjacent conductive pillars was 300 (V/m).

As described, in the wiring board according to the embodiment, the electric field strength of electromagnetic waves leaking from the waveguide was reduced to 1/10 compared to the wiring board according to the comparative example,

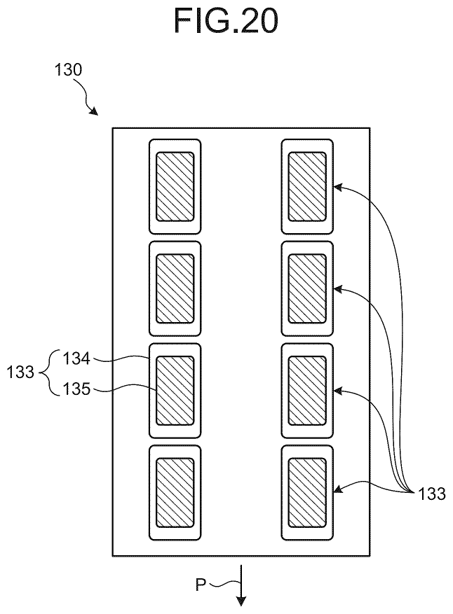

Next, various modifications of the embodiment will be explained referring to FIG. 20 to FIG. 23. In the respective modifications described below, identical reference symbols are assigned to parts identical to those of the embodiment, and duplicated explanation can thereby be omitted.

FIG. 20 is a cross-section of the waveguide 130 according to a first modification of the embodiment cut on a plane perpendicular to the lamination direction. In the waveguide 130 according to the first modification, shapes of the via 135 and the connection pad 134 are different from those of the embodiment.

Specifically, in the first modification, a cross section perpendicular to the lamination direction of the via 135 of the respective conductive pillars 133 is in a rectangular shape with its long sides extending in the propagation direction P of electromagnetic waves. Thus, reflection of electromagnetic waves in the respective conductive pillars 133 can be promoted compared to a case in which a cross-section perpendicular to the lamination direction of the via 135 is in a square shape. Therefore, it is possible to improve transmission characteristics of the waveguide 130 along the propagation direction P of electromagnetic waves.

Moreover, in the first modification, the respective connection pads 134 of the respective conductive pillars 133 are in a rectangular shape with its long sides extending in the propagation direction P of electromagnetic waves in plan view. Thus, reflection of electromagnetic waves in the respective conductive pillars 133 can be promoted compared to a case in which the respective connection pads 134 are in a square shape in plan view. Therefore, it is possible to improve transmission characteristics of the waveguide 130 along the propagation direction P of electromagnetic waves.

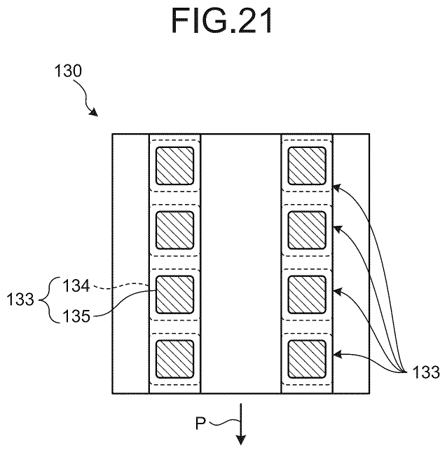

FIG. 21 is a cross-section of the waveguide 130 according to a second modification of the embodiment cut on a plane perpendicular to the lamination direction. In the waveguide 130 according to the second modification, a shape of the connection pad 134 is different from that of the embodiment.

Specifically, in the second modification, out of the connection pads 134 belonging to the same layer in the respective rows of the multiple conductive pillars 133, two or more adjacent connection pads 134 are connected to each other to form a pattern. Thus, compared to a case in which the adjacent connection pads 134 are not connected to each other, dispersion of electromagnetic waves at the corners of the connection pad 134 can be suppressed. Therefore, it is possible to improve the transmission characteristics of the waveguide 130 along the propagation direction P of electromagnetic waves.

In the example of FIG. 21, adjacent four connection pads 134 are connected to one another to form a pattern in the respective rows of the conductive pillars 133. The number of the connection pads 134 that form a pattern is not limited to four, and two or more is acceptable.

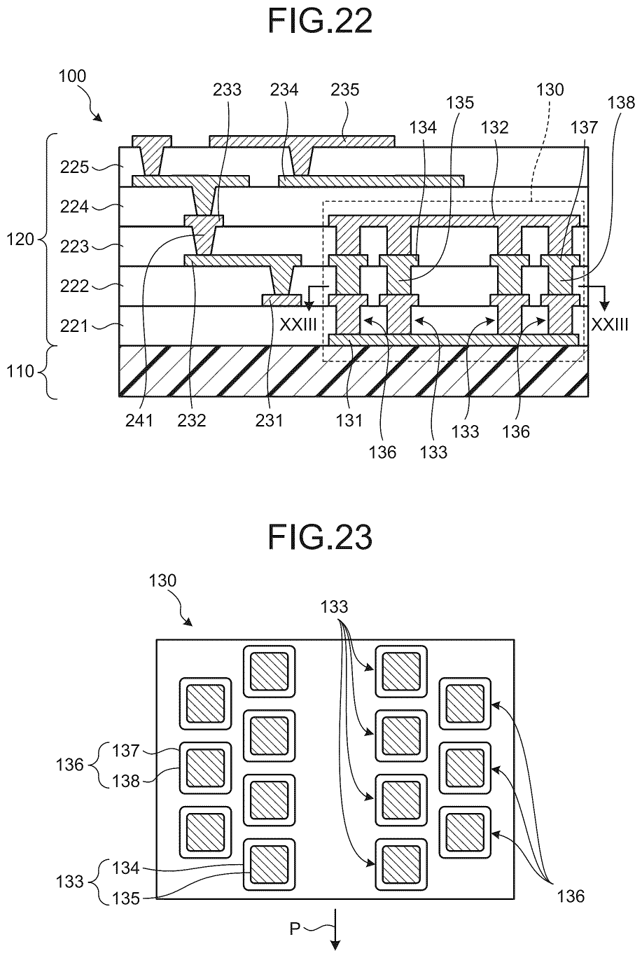

FIG. 22 is a diagram illustrating a configuration of the wiring board 100 according to a third modification of the embodiment. The wiring board 100 according to the third modification differs from the embodiment in a point that a conductive pillar different from the conductive pillar 133 is provided in the waveguide 130. Specifically, in the third modification, the waveguide 130 further includes multiple conductive pillars 136 in addition to the first conductive layer 131, the second conductive layer 132, and the conductive pillars 133. The multiple conductive pillars 136 are arranged in a region between the first conductive layer 131 and the second conductive layer 132, and outside the multiple conductive pillars 133 in two rows along the propagation direction P of electromagnetic waves, and connect the first conductive layer 131 and the second conductive layer 132.

The respective conductive pillars 136 are formed by laminating multiple connection pads 137 (two layers in the example in FIG. 22) between the first conductive layer 131 and the second conductive layer 132, and by connecting the connection pad 137 of the adjacent layer with a via 138.

As described, in the third modification, the multiple conductive pillars 136 are arranged in the region outside the multiple conductive pillars 133. Therefore, it is possible to further reduce the possibility of electromagnetic waves passing through a gap between the adjacent conductive pillars 133 to the outside of the waveguide 130. As a result, it is possible to further reduce leakage of electromagnetic waves from the waveguide 130.

FIG. 23 is a cross-section of the waveguide 130 according to the third modification of the embodiment cut on a plane perpendicular to the lamination direction. FIG. 23 corresponds to a cross-section of the waveguide 130 cut along a line XXIII-XXIII in FIG. 22.

In the third modification, the via 138 of the respective conductive pillars 136 has a cross-section perpendicular to the lamination direction in a rectangular shape (square as an example in FIG. 23). That is, the via 138 has a prismatic shape as a whole. Therefore, it is possible to reduce the gap between the adjacent conductive pillars 136 compared to a case in which a cross-section perpendicular to the lamination direction of the via of the respective conductive pillars is in a circular shape (that is, when a via has a cylindrical shape). This enables to further reduce the possibility of electromagnetic waves passing through a gap between the adjacent conductive pillars 133 to the outside of the waveguide 130. As a result, it is possible to further reduce leakage of electromagnetic waves from the waveguide 130.

Moreover, in the third modification, the cross-section perpendicular to the lamination direction may be in a rounded rectangular shape. That is, four corners of the rectangular via 138 may be rounded. This enables to reduce concentration of a stress due to a difference in thermal expansion coefficients of the insulating resin and the via 138 caused on corners of via holes formed in the insulating layers 221 and 222 (refer to FIG. 22) for the via 138 in a rectangular shape. As a result, it is possible to reduce a possibility of delamination and damage of the insulating layers 221, 222, and the via 138.

Furthermore, in the third modification, the respective connection pads 137 of the respective conductive pillars 136 have a rectangular shape in plan view (square shape as an example in FIG. 23). Therefore, it is possible to further reduce the gap partially between the adjacent conductive pillars 136 compared to a case in which the connection pads of the respective conductive pillars have a circular shape in plan view. This enables to further reduce the possibility of electromagnetic waves passing through a gap between the adjacent conductive pillars 136 to the outside of the waveguide 130. As a result, it is possible to further suppress leakage of electromagnetic waves from the waveguide 130.

Moreover, in the third modification, respective connection pads 137 may be in a rounded rectangular shape in plan view. That is, four corners of the respective connection pads 137 in a rectangular shape may be rounded. This enables to reduce concentration of a stress due to a difference in thermal expansion coefficients of the insulating resin and the respective connection pads 137 caused on the insulating layers 222, 223 (refer to FIG. 22) that cover the respective connection pads 137 in a rectangular shape. As a result, it is possible to suppress a possibility of delamination and damage of the insulating layers 222, 223, and the respective connection pads 137.

Moreover, in the third modification, the respective conductive pillars 136 are arranged at a position overlapping with the gap between the adjacent conductive pillars 133 in a side view. This enables to further reduce a possibility of electromagnetic waves passing through the gap between the adjacent conductive pillars 133 to the outside of the waveguide 130. As a result, it is possible to further suppress leakage of electromagnetic waves from the waveguide 130.

As described above, the wiring board (the wiring board 100 as an example) according to the embodiment includes a layered structure (the multilayer wiring structure 120 as an example) and a waveguide (the waveguide 130 as an example). The layered structure includes multiple insulating layers (the insulating layers 221 to 225 as an example) that are laminated. The waveguide is formed inside the layered structure. The waveguide includes a pair of conductive layers (the first conductive layer 131 and the second conductive layer 132 as an example), and multiple conductive pillars (the conductive pillars 133 as an example). The pair of conductive layers face each other in a lamination direction of the multiple insulating layers. The conductive pillars are arranged in two rows along a propagation direction (the propagation direction P as an example) of electromagnetic waves between the pair of conductive layers, and connect the pair of conductive layers. The respective conductive pillars have multiple connection pads (the connection pads 134 as an example) and a via (the via 135 as an example). The multiple connection pads are laminated between the pair of the conductive layers. The via connects the connection pads of adjacent layers, and has a cross-section perpendicular to the lamination direction in a rectangular shape. This enables to suppress leakage of electromagnetic waves from the waveguide.

According to one aspect of the wiring board disclosed in the present application, an effect of suppressing leakage of electromagnetic waves from a waveguide is produced.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
a layered structure including a plurality of insulating layers that are laminated; and
a waveguide that is formed inside the layered structure, wherein
the waveguide includes
a pair of conductive layers facing each other in a lamination direction of the insulating layers; and
a plurality of conductive pillars that are arranged in two rows along a propagation direction of electromagnetic waves between the pair of the conductive layers, and that connect the pair of the conductive layers, and
the respective conductive pillars include
a plurality of connection pads that are laminated between the pair of conductive layers; and
a via that connects the connection pads of adjacent layers, and that has a cross-section perpendicular to the lamination direction in a rectangular shape.

2. The wiring board according to claim 1, wherein
the via has a cross-section perpendicular to the lamination direction in a rectangular shape with long sides thereof extending in the propagation direction of electromagnetic waves.

3. The wiring board according to claim 1, wherein
the via has a cross-section perpendicular to the lamination direction in a rounded rectangular shape.

4. The wiring board according to claim 1, wherein
the respective connection pads are in a rectangular shape in plan view.

5. The wiring board according to claim 4, wherein
the respective connection pads are in a rectangular shape with long sides thereof extending in the propagation direction of electromagnetic waves in plan view.

6. The wiring board according to claim 4, wherein
the respective connection pads are in a rounded rectangular shape in plan view.

7. The wiring board according to claim 1, wherein
out of the connection pads belonging to an identical layer in respective rows of the conductive pillars, two or more adjacent connection pads are connected to one another to form a pattern.

8. The wiring board according to claim 1, wherein
the waveguide further includes a plurality of other conductive pillars that are arranged in two rows along the propagation direction of electromagnetic waves in a region between the pair of the conductive layers and outside the conductive pillars, and that connect the pair of the conductive layers.

9. The wiring board according to claim 8, wherein
the respective other conductive pillars include
a plurality of other connection pads that are laminated between the pair of the conductive layers; and
another via that connects the other connection pads of adjacent layers, and that has a cross-section perpendicular to the lamination direction in a rectangular shape.

10. The wiring board according to claim 8, wherein
the respective other conductive pillars are arranged at a position overlapping with a gap between the adjacent conductive pillars in a side view.
